(19) United States
(12) Patent Application Publication
(10) Pub. No.: US 2025/0241189 A1
(43) Pub. Date: Jul. 24, 2025

(54) DISPLAY DEVICE AND OPTICAL DEVICE

(71) Applicant: Samsung Display Co., LTD., Yongin-si (KR)

(72) Inventors: Young Gu KIM, Yongin-si (KR); Su Jeong KIM, Yongin-si (KR); Seung Beom PARK, Yongin-si (KR); Baek Kyun JEON, Yongin-si (KR)

(73) Assignee: Samsung Display Co., LTD., Yongin-si (KR)

(21) Appl. No.: 18/828,113

(22) Filed: Sep. 9, 2024

(30) Foreign Application Priority Data
Jan. 24, 2024 (KR) 10-2024-0010964

(51) Int. Cl. H10K 59/80; G02B 5/30; G02B 27/01; H10K 59/38

(52) U.S. Cl. CPC H10K 59/8793; G02B 5/3058; G02B 5/3083; G02B 27/0172; H10K 59/38; H10K 59/879; G02B 2027/0178

(57) ABSTRACT

A display device includes a first electrode on a substrate, an emissive layer on the first electrode, a second electrode on the emissive layer, and a wire grid polarizer on the second electrode. The wire grid polarizer includes a plurality of grid patterns, and a pitch between the plurality of grid patterns arranged in a blue emission area of a blue pixel providing blue light is smaller than pitches between the plurality of grid patterns arranged in emission areas of pixels providing different lights from the blue light in a horizontal direction.

### CROSS REFERENCE TO RELATED APPLICATION(S)

This application claims priority to and benefits of Korean Patent Application No. 10-2024-0010964 under 35 U.S.C. § 119, filed on Jan. 24, 2024, in the Korean Intellectual Property Office (KIPO), the entire contents of which are incorporated herein by reference.

### BACKGROUND

### 1. Technical Field

The disclosure relates to a display device and an optical device that can improve transmittance in a short-wavelength range and improve luminance balance.

### 2. Description of the Related Art

A head-mounted display (HMD) is an image display device that can be worn on a user's body in the form of glasses or a helmet to form a focus close to the user's eyes. A head-mounted display can implement virtual reality (VR) or augmented reality (AR).

A head-mounted display magnifies images displayed by a small display device using multiple lenses to display the images. Therefore, a display device applied to a head-mounted display may be required to provide high-resolution images, for example, images with a resolution of 3,000 PPI (pixels per inch) or higher. To this end, OLEDoS (organic light-emitting diode on silicon), which is a small, high-resolution organic light-emitting display device, is used as the display device applied to a head-mounted display. The OLEDoS is a device that displays images in which organic light-emitting diodes (OLED) are disposed on a semiconductor wafer substrate where complementary metal oxide semiconductor (CMOS) is disposed.

### SUMMARY

Aspects of the disclosure provide a display device and an optical device that can improve transmittance in a short-wavelength range and improve luminance balance.

According to an embodiment of the disclosure, a display device may include a first electrode on a substrate, an emissive layer on the first electrode, a second electrode on the emissive layer, and a wire grid polarizer on the second electrode. The wire grid polarizer may include a plurality of grid patterns, and a pitch between the plurality of grid patterns arranged in a blue emission area of a blue pixel providing blue light is smaller than pitches between the plurality of grid patterns arranged in emission areas of pixels providing different lights from the blue light in a horizontal direction.

In an embodiment, the pixels providing the different lights may include a green pixel providing green light, and a red pixel providing red light.

In an embodiment, the pitch between the plurality of grid patterns arranged in a green emission area of the green pixel and the pitch between the plurality of grid patterns arranged in a red emission area of the red pixel may be equal.

In an embodiment, the display device may further include a phase retardation layer between the second electrode and the wire grid polarizer.

In an embodiment, the display device may further include a color filter layer between the second electrode and the wire grid polarizer.

In an embodiment, the color filter layer may include a red color filter that transmits red light, a green color filter that transmits green light, and a blue color filter that transmits the blue light.

In an embodiment, a pitch between the plurality of grid patterns arranged in line with the blue color filter may be smaller than a pitch between the plurality of grid patterns arranged in line with the green color filter.

In an embodiment, a pitch between the plurality of grid patterns arranged in line with the blue color filter may be smaller than a pitch between the plurality of grid patterns arranged in line with the red color filter.

In an embodiment, the pitch between the plurality of grid patterns arranged in the blue emission area may be in a range of about 50 nm to about 90 nm.

In an embodiment, the pitches between the plurality of grid patterns arranged in the emission areas of the pixels providing the different lights may be in a range of 100 nm to 150 nm.

In an embodiment, at least one of the plurality of grid patterns of the wire grid polarizer has a thickness in a range of about 100 nm to about 300 nm.

In an embodiment, the wire grid polarizer may include at least one of aluminum, silver, and gold.

In an embodiment, the display device may further include a lens layer between the second electrode and the wire grid polarizer.

In an embodiment, the display device may further include a lens layer on the wire grid polarizer.

According to an embodiment of the disclosure, an optical device may include a display device, and an optical path conversion member above the display device. The display device may include a first electrode on a substrate, an emissive layer on the first electrode, a second electrode on the emissive layer, and a wire grid polarizer on the second electrode. The wire grid polarizer may include a plurality of grid patterns, and a pitch between the plurality of grid patterns arranged in a blue emission area of a blue pixel providing blue light may be smaller than pitches between the plurality of grid patterns arranged in emission areas of pixels providing different lights from the blue light in a horizontal direction.

In an embodiment, the pixels providing the different lights may include a green pixel providing green light, and a red pixel providing red light.

In an embodiment, the pitch between the plurality of grid patterns arranged in a green emission area of the green pixel and the pitch between the plurality of grid patterns arranged in a red emission area of the red pixel may be equal.

In an embodiment, the optical device may further include a phase retardation layer between the second electrode and the wire grid polarizer.

In an embodiment, the optical device may further include a color filter layer between the second electrode and the wire grid polarizer.

In an embodiment, the color filter layer may include a red color filter that transmits red light, a green color filter that transmits green light, and a blue color filter that transmits the blue light.

In an embodiment, a pitch between the plurality of grid patterns arranged in line with the blue color filter may be smaller than a pitch between the plurality of grid patterns arranged in line with the green color filter.

In an embodiment, a pitch between the plurality of grid patterns arranged in line with the blue color filter may be smaller than a pitch between the plurality of grid patterns arranged in line with the red color filter.

According to an embodiment of the disclosure, transmittance in a short-wavelength range and luminance balance may be improved in a display device and an optical device.

In addition, according to an embodiment of the disclosure, an alignment-free structure may be achieved by maintaining a same pitch of red pixels and green pixels in a high-resolution pixel arrangement in a display device, thereby improving the alignment margin. Accordingly, the efficiency of the process may be improved.

The effects of the disclosure are not limited to the above-described effects and other effects which are not described herein will become apparent to those skilled in the art from the following description.

### BRIEF DESCRIPTION OF THE DRAWINGS

The above and other aspects and features of the disclosure will become more apparent by describing in detail embodiments thereof with reference to the attached drawings, in which:

FIG. 1 is an exploded, perspective view of a display device according to an embodiment of the disclosure.

FIG. 2 is a plan view illustrating a layout of the display panel shown in FIG. 1 according to an embodiment of the disclosure.

FIG. 3 is a schematic diagram of an equivalent circuit of a first pixel according to an embodiment of the disclosure.

FIG. 4 is a plan view illustrating a layout of a display panel according to an embodiment of the disclosure.

FIG. 5 is a plan view illustrating a layout of the display area of FIG. 4 according to an embodiment.

FIG. 6 is a schematic cross-sectional view of the display panel taken along line X-X′ of FIG. 5 according to an embodiment.

FIG. 7 is a schematic cross-sectional view of the display panel taken along line X-X′ of FIG. 5 according to an embodiment.

FIG. 8 is a schematic cross-sectional view of the display panel taken along line X-X′ of FIG. 5 according to an embodiment.

FIG. 9 is a schematic cross-sectional view of the display panel taken along line X-X′ of FIG. 5 according to an embodiment.

FIG. 10 is a graph for illustrating the effects of a display device according to an embodiment.

FIG. 11 is a perspective view showing a head-mounted display according to an embodiment of the disclosure.

FIG. 12 is an exploded perspective view of the head-mounted display of FIG. 11 according to an embodiment.

FIG. 13 is a perspective view showing a head-mounted display according to an embodiment of the disclosure.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the disclosure may be combined partially or totally. As will be clearly appreciated by those skilled in the art, technically various interactions and operations are possible. Various embodiments can be practiced individually or in combination.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described in detail with reference to the accompanying drawings.

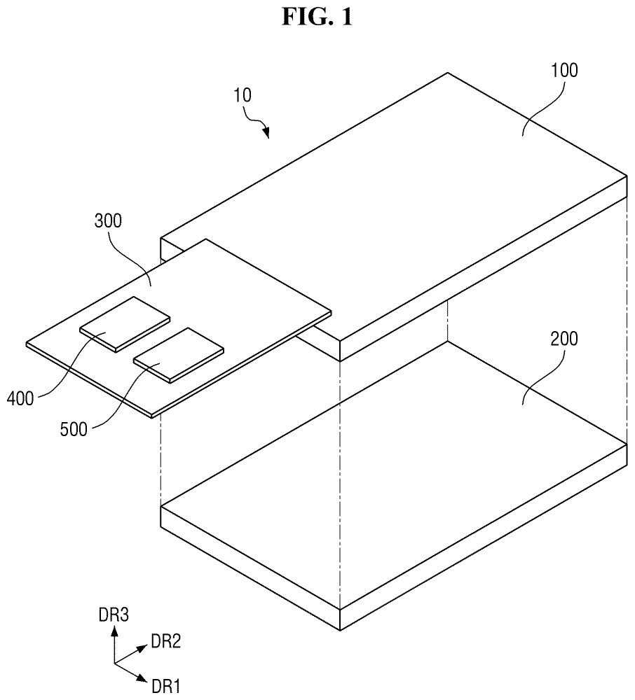

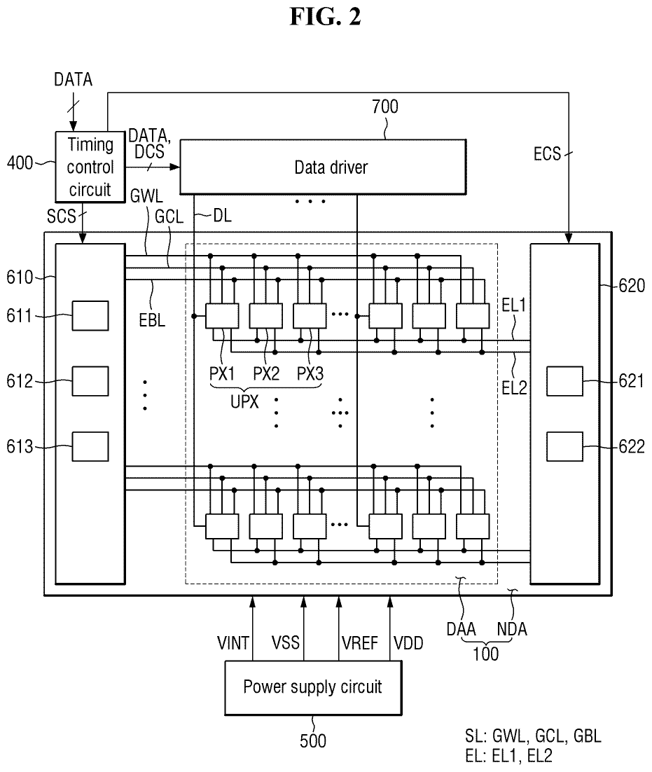

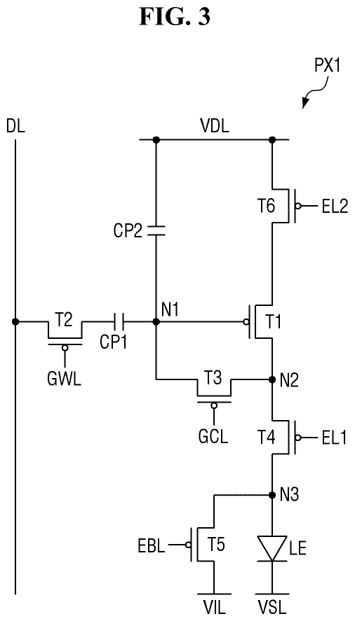

FIG. 1 is an exploded, perspective view of a display device according to an embodiment of the disclosure. FIG. 2 is a plan view illustrating a layout of the display panel shown in FIG. 1 according to an embodiment of the disclosure. FIG. 3 is a schematic diagram of an equivalent circuit of a first pixel according to an embodiment of the disclosure.

FIG. 1 is an exploded, perspective view of a display device according to an embodiment of the disclosure. FIG. 2 is a schematic block diagram showing a display device according to an embodiment of the disclosure.

Referring to FIGS. 1 and 2, the display device 10 according to the embodiment may display a moving image or a still image. The display device 10 according to the embodiment may be employed by portable electronic devices such as a mobile phone, a smart phone, a tablet PC, a mobile communications terminal, an electronic notebook, an electronic book, a portable multimedia player (PMP), a navigation device and an ultra mobile PC (UMPC). For example, the display device 10 according to the embodiment of the disclosure may be used as a display unit of a television, a laptop computer, a monitor, an electronic billboard, or the Internet of Things (IoT). For example, the display device 10 according to the embodiment of the disclosure may be applied to a smart watch, a watch phone, or a head-mounted display (HMD) for implementing virtual reality and augmented reality.

According to an embodiment, the display device 10 may include a display panel 100, a heat dissipation layer 200, a circuit board 300, a timing control circuit 400, and a power supply circuit 500.

The display panel 100 may have a shape similarly to a rectangular shape in a plan view. For example, the display panel 100 may have a shape similar to a rectangle having shorter sides in the first direction DR1 and longer sides in the second direction DR2 intersecting the first direction DR1 in a plan view. In the display panel 100, the corners where the shorter sides in the first direction DR1 meet the longer sides in the second direction DR2 may be rounded with a curvature or may be a right angle. The shape of the display panel 100 in a plan view is not limited to a rectangular shape, but may be formed in a shape similar to other polygonal shapes, a circular shape, or an elliptical shape. The shape of the display device 10 may follow the shape of the display panel 100 in a plan view, but the embodiments of the disclosure are not limited thereto.

The display panel 100 may include a display area DAA where images are displayed, and a non-display area NDA where no image is displayed as shown in FIG. 2.

The display area DAA may include multiple pixels PX, multiple scan lines SL, multiple emission control lines EL, and multiple data lines DL.

The pixels PX may be arranged in a matrix in the first direction DR1 and the second direction DR2. The scan lines SL and the emission control lines EL may be extended in the first direction DR1 and may be arranged in the second direction DR2. The data lines DL may be extended in the second direction DR2 and may be arranged in the first direction DR1.

The scan lines SL may include multiple write scan lines GWL, multiple control scan lines GCL, and multiple bias scan lines GBL. The emission control lines EL may include multiple first emission control lines EL1 and multiple second emission control lines EL2.

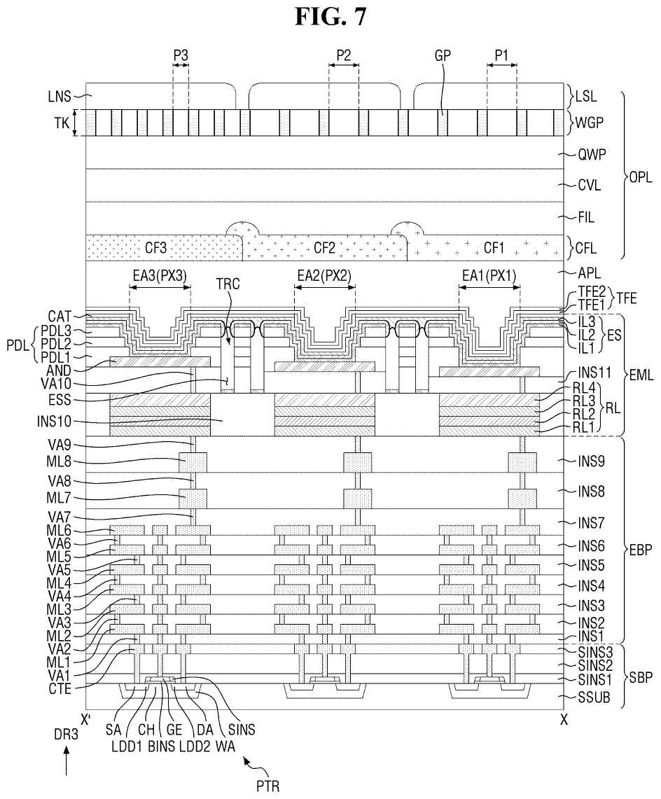

Multiple unit pixels PX may include multiple pixels PX1, PX2 and PX3. Each of the pixels PX1, PX2 and PX3 may include multiple pixel transistors as shown in FIG. 3. The pixel transistors may be formed by a semiconductor process and may be disposed on a semiconductor substrate SSUB (see FIG. 7). For example, the pixel transistors of a data driver 700 may be implemented as complementary metal oxide semiconductor (CMOS).

Each of the pixels PX1, PX2 and PX3 may be connected to one of the write scan lines GWL, one of the control scan lines GCL, one of the bias scan lines GBL, one of the first emission control lines EL1, one of the second emission control lines EL2, and one of the data lines DL. Each of the pixels PX1, PX2 and PX3 may receive a data voltage from the data line DL according to the write scan signal from the write scan line GWL, and may allow the light-emitting elements to emit light according to the data voltage.

The display panel 100 may include a scan driver 610, an emission driver 620, and the data driver 700 in the non-display area NDA.

The scan driver 610 may include multiple scan transistors, and the emission driver 620 may include multiple light-emitting transistors. Multiple scan transistors and multiple light-emitting transistors may be formed by a semiconductor process and may be formed on the semiconductor substrate SSUB (see FIG. 7). For example, multiple scan transistors and multiple light-emitting transistors may be formed of CMOS. Although the scan driver 610 is disposed on the left side of the display area DAA and the emission driver 620 is disposed on the right side of the display area DAA in the embodiment shown in FIG. 2, the embodiment of the disclosure is not limited thereto. For example, the scan driver 610 and the emission driver 620 may be disposed on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612 and the bias scan signal output unit 613 may receive a scan timing control signal SCS from the timing control circuit 400. The write scan signal output unit 611 may generate write scan signals according to the scan timing control signal SCS from the timing control circuit 400 and sequentially output them to the write scan lines GWL. The control scan signal output unit 612 may generate control scan signals according to the scan timing control signal SCS and sequentially output them to the control scan lines GCL. The bias scan signal output unit 613 may generate bias scan signals according to the scan timing control signal SCS and sequentially output them to the bias scan lines EBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include multiple data transistors, and the data transistors may be formed by a semiconductor process and may be formed on the semiconductor substrate SSUB (see FIG. 7). For example, the data transistors may be formed of CMOS.

The data driver 700 may receive digital video data DATA and a data timing control signal DCS from the timing control circuit 400. The data driver 700 may convert the digital video data DATA into analog data voltages according to the data timing control signal DCS and output them to the data lines DL. The pixels PX1, PX2 and PX3 may be selected by the write scan signal of the scan driver 610, and data voltages may be applied to the selected pixels PX1, PX2 and PX3.

The heat dissipation layer 200 may overlap the display panel 100 in a third direction DR3, which is a thickness direction of the display panel 100. The heat dissipation layer 200 may be disposed on a surface of the display panel 100, e.g., on a rear surface. The heat dissipation layer 200 may serve to discharge heat generated in the display panel 100. The heat dissipation layer 130 may include a conductive layer including a material such as graphite, silver (Ag), copper (Cu) and aluminum (Al) having a high thermal conductivity.

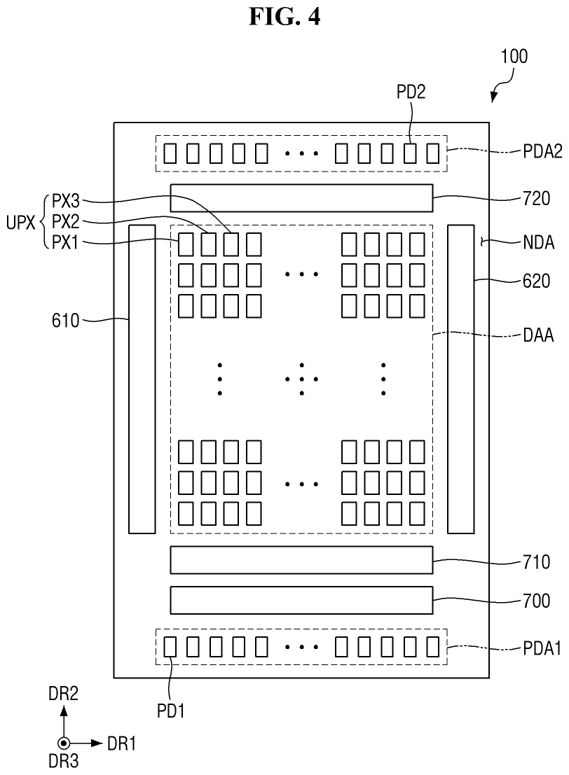

The circuit board 300 may be electrically connected to multiple first pads PD1 (see FIG. 4) of a first pad area PDA1 (see FIG. 4) of the display panel 100 using a conductive adhesive member such as an anisotropic conductive film. The circuit board 300 may be a flexible printed circuit board made of a flexible material, or a flexible film. Although the circuit board 300 is unfolded in FIG. 1, the circuit board 300 may be bent. In case that the circuit board 300 is bent, an end of the circuit board 300 may be disposed on the rear surface of the display panel 100 and/or the rear surface of the heat dissipation layer 200. The end of the circuit board 300 may be opposite to another end of the circuit board 300, which is connected to the first pads PD1 (see FIG. 4) of the first pad area PDA1 (see FIG. 4) of the display panel 100 using a conductive adhesive member.

The timing control circuit 400 may receive digital video data and timing signals from the outside. The timing control circuit 400 may generate a scan timing control signal SCS, an emission timing control signal ECS, and a data timing control signal DCS for controlling the display panel 100 in response to the timing signals. The timing control circuit 400 may output the scan timing control signal SCS to the scan driver 610 and output the emission timing control signal ECS to the emission driver 620. The timing control circuit 400 may output the digital video data DATA and the data timing control signal DCS to the data driver 700.

A power supply circuit 500 may generate multiple panel driving voltages in response to a supply voltage from the outside. For example, the power supply circuit 500 may generate a first supply voltage VSS, a second supply voltage VDD, and a third supply voltage VINT to apply them to the display panel 100. The first supply voltage VSS, the second supply voltage VDD and the third supply voltage VINT will be described below with reference to FIG. 3.

Each of the timing control circuit 400 and the power supply circuit 500 may be implemented as an integrated circuit (IC) and attached to a surface of the circuit board 300. The scan timing control signal SCS, the emission timing control signal ECS, the digital video data DATA and the data timing control signal DCS from the timing control circuit 400 may be supplied to the display panel 100 through the circuit board 300. The first supply voltage VSS, the second supply voltage VDD and the third supply voltage VINT of the power supply circuit 500 may be supplied to the display panel 100 through the circuit board 300.

In another embodiment, each of the timing control circuit 400 and the power supply circuit 500 may be disposed in the non-display area NDA of the display panel 100, similarly to the scan driver 610, the emission driver 620 and the data driver 700. The timing control circuit 400 may include multiple timing transistors, and each power supply circuit 500 may include multiple power transistors. Multiple timing transistors and multiple power transistors may be formed by a semiconductor process and may be formed on the semiconductor substrate SSUB (see FIG. 7). For example, the timing transistors and the power transistors may be formed of CMOS. Each of the timing control circuit 400 and the power supply circuit 500 may be disposed between the data driver 700 and the first pad area PDA1 (see FIG. 4).

FIG. 3 is a schematic diagram of an equivalent circuit of a first pixel according to an embodiment of the disclosure.

Referring to FIG. 3, a first pixel PX1 may be connected to a write scan line GWL, a control scan line GCL, a bias scan line EBL, a first emission control line EL1, a second emission control line EL2 and a data line DL. The first pixel PX1 may be connected to a first supply voltage line VSL where the first supply voltage VSS equal to a low-level voltage is applied, a second supply voltage line VDL where the second supply voltage VDD equal to a high-level voltage is applied, and a third supply voltage line VIL where the third supply voltage VINT equal to an initialization voltage is applied. In other words, the first supply voltage line VSL may be a low-level voltage line, the second supply voltage line VDL may be a high-level voltage line, and the third supply voltage line VIL may be an initialization voltage line. The first supply voltage VSS may be lower than the third supply voltage VINT. The second supply voltage VDD may be higher than the third supply voltage VINT.

The first pixel PX1 may include multiple transistors T1 to T6, a light-emitting element LE, a first capacitor CP1, and a second capacitor CP2.

The light-emitting element LE may emit light according to a driving current flowing from a channel of the first transistor T1. The amount of the light emitted from the light-emitting element LE may be proportional to the driving current. The light-emitting element LE may be disposed between the fourth transistor T4 and the first supply voltage line VSL. The first electrode of the light-emitting element LE may be connected to a drain electrode of the fourth transistor T4, and the second electrode of the fourth transistor T4 may be connected to the first supply voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode. It should be understood, however, that the disclosure is not limited thereto. For example, the light-emitting element LE may be an inorganic light-emitting element including a first electrode, a second electrode, and an inorganic semiconductor disposed between the first electrode and the second electrode. The light-emitting element LE may be a micro light-emitting diode.

The first transistor T1 may be a driving transistor for controlling the source-drain current (hereinafter referred to as “driving current”) flowing between the source electrode and the drain electrode according to the voltage applied to the gate electrode. The first transistor T1 may include a gate electrode connected to a first node N1, a source electrode connected to a drain electrode of the sixth transistor T6, and a drain electrode connected to a second node N2.

The second transistor T2 may be disposed between an electrode of the first capacitor CP1 and the data line DL. The second transistor T2 may be turned on by a write scan signal from the write scan line GWL and connect the electrode of the first capacitor CP1 to the data line DL. Accordingly, the data voltage of the data line DL may be applied to the electrode of the first capacitor CP1. The second transistor ST2 may include a gate electrode connected to the write scan line GWL, a source electrode connected to the data line DL, and a drain electrode connected to the electrode of the first capacitor CP1.

A third transistor T3 may be connected between the first node N1 and the second node N2. The third transistor T3 may be turned on by the write control signal of the write control line GCL and connect the first node N1 to the second node N2. Accordingly, the gate electrode and source electrode of the first transistor T1 may be connected with each other, and thus the first transistor T1 may act like a diode. The third transistor T3 may include a gate electrode connected to the write control line GCL, a source electrode connected to the second node N2, and a drain electrode connected to the first node N1.

The fourth transistor T4 may be connected between the second node N2 and the third node N3. The fourth transistor ST4 may be turned on by a first emission control signal of the first emission control line EL1 and connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

The fifth transistor T5 may be disposed between the third node N3 and the third supply voltage line VIL. The fifth transistor T5 may be turned on by a bias scan signal of the bias scan line EBL and connect the third node N3 to the third supply voltage line VIL. Accordingly, the third supply voltage VINT of the third supply voltage line VIL may be applied to the first electrode of the light-emitting element LE. The fifth transistor T5 may include a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 and connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be formed between the first node N1 and the drain electrode of the second transistor T2. The first capacitor CP1 may include a first electrode connected to the drain electrode of the second transistor T2, and a second electrode connected to the first node N1.

The second capacitor CP2 may be formed between the gate electrode of the driving transistor DT and the second driving voltage line VDL. The second capacitor CP2 may include a first electrode connected to the gate electrode of the first transistor T1 and a second electrode connected to the second driving voltage line VDL.

The first node N1 may be a contact point where the gate electrode of the first transistor T1, the drain electrode of the third transistor T3, the second electrode of the first capacitor CP1 and the first electrode of the second capacitor CP2 meet. The second node N2 may be a contact point where the drain electrode of the first transistor T1, the source electrode of the third transistor T3 and the source electrode of the fourth transistor T4 meet. The third node N3 may be a contact point where the drain electrode of the fourth transistor T4, the source electrode of the fifth transistor T5, and the first electrode of the light-emitting element LE meet.

Each of the first to sixth transistors T1 to T6 may be a metal-oxide-semiconductor field effect transistor (MOSFET). For example, each of the first to sixth transistors T1 to T6 may be, but is not limited to, a p-type MOSFET. In another embodiment, each of the first to sixth transistors T1 to T6 may be an n-type MOSFET. In another embodiment, some of the first to sixth transistors T1 to T6 may be p-type MOSFETs, and other transistors may be n-type MOSFETs.

Although the first pixel PX1 includes the six transistors T1 to T6 and the two capacitors C1 and C2 in the embodiment shown in FIG. 3, it should be noted that the equivalent circuit diagram of the pixel PX1 is not limited to that shown in FIG. 3. For example, the numbers of the transistors and the capacitors of the first pixel PX1 are not limited to those shown in FIG. 3.

The equivalent circuit diagram of the second pixel PX2 and the equivalent circuit diagram of the third pixel PX3 may be substantially identical to the equivalent circuit diagram of the first pixel PX1 described above with reference to FIG. 3; and, therefore, the redundant descriptions will be omitted.

FIG. 4 is a plan view illustrating a layout of a display panel according to an embodiment of the disclosure.

Referring to FIG. 4, the display area DAA of the display panel 100 according to an embodiment may include multiple pixels PX arranged in a matrix. The non-display area NDA of the display panel 100 according to an embodiment may include the scan driver 610, the emission driver 620, the data driver 700, a first distribution circuit 710, a second distribution circuit 720, a first pad area PDA1, and a second pad area PDA2.

The scan driver 610 may be disposed on a first side of the display area DAA, and the emission driver 620 may be disposed on a second side of the display area DAA. For example, the scan driver 610 may be disposed on a side of the display area DAA in the first direction DR1, and the emission driver 620 may be disposed on an opposite side of the display area DAA in the first direction DR1. For example, the scan driver 610 may be disposed on the left side of the display area DAA, and the emission driver 620 may be disposed on the right side of the display area DAA in a plan view. It should be understood, however, that the embodiments of the disclosure are not limited thereto. The scan driver 610 and the emission driver 620 may be disposed on both the first and second sides of the display area DAA.

The first pad area PDA1 may include multiple first pads PD1 connected to pads or bumps of the circuit board 300 through a conductive adhesive member. The first pad area PDA1 may be disposed on a third side of the display area DAA. For example, the first pad area PDA1 may be located on a side of the display area DAA in the second direction DR2.

The first pad area PDA1 may be located on a side of the data driver 700 in the second direction DR2. For example, the first pad area PDA1 may be located closer to the edge of the display panel 100 than the data driver 700.

The second pad area PDA2 may include multiple second pads PD2 which is test pads for testing whether the display panel 100 operates normally. The second pads PD2 may be connected to a jig or a probe pin during a test process, or may be connected to a circuit board for testing. The circuit board for testing may be a printed circuit board made of a rigid material or a flexible printed circuit board made of a flexible material.

The first distribution circuit 710 may distribute data voltages applied via the first pad area PDA1 to multiple data lines DL. For example, the first distribution circuit 710 may divide the data voltages applied via a first pad PD1 of the first pad area PDA1 into P data lines DL, thereby reducing the number of the first pads PD1, where P is a positive integer equal to or greater than two. The first distribution circuit 710 may be disposed on the third side of the display area DAA of the display panel 100. For example, the first distribution circuit 710 may be disposed on a side of the display area DAA in the second direction DR2. For example, the first distribution circuit 710 may be disposed on the lower side of the display area DAA in a plan view.

The second distribution circuit 720 may distribute signals applied through the second pad area PDA2 to the scan driver 610, the emission driver 620, and the data lines DL. The second pad area PDA2 and the second distribution circuit 720 may be elements to test the operation of each of the pixels PX in the display area DAA. The second distribution circuit 720 may be disposed on a fourth side of the display area DAA of the display panel 100. For example, the second distribution circuit 720 may be disposed on a side of the display area DAA in the second direction DR2. For example, the second distribution circuit 720 may be disposed on the upper side of the display area DAA in a plan view.

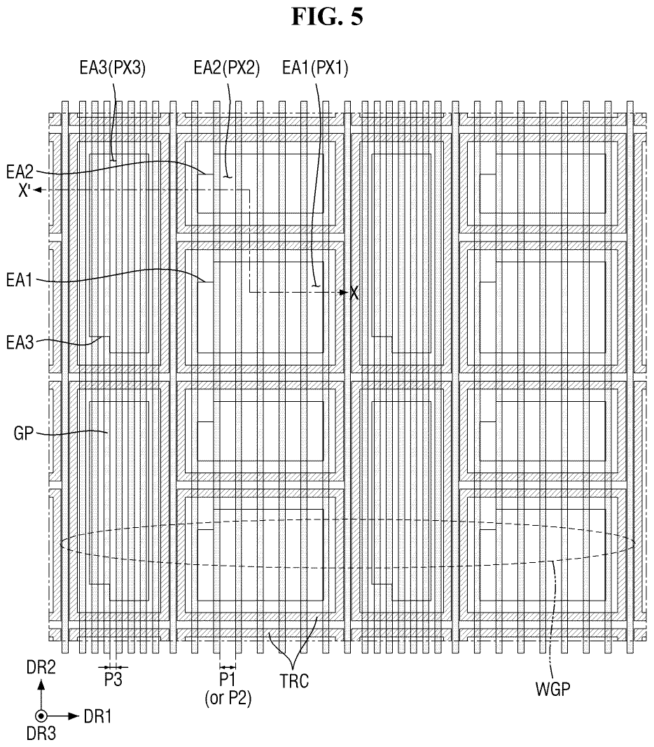

FIG. 5 is a plan view illustrating a layout of the display area of FIG. 4 according to an embodiment.

Referring to FIG. 5, each of the unit pixels UPX may include a first emission area EA1 that is the emission area of the first pixel PX1, a second emission area EA2 that is the emission area of the second pixel PX2, and a third emission area EA3 that is the emission area of the third pixel PX3. For example, a unit pixel UPX may include a unit emission area, and the unit emission area UEA may include a first emission area EA1, a second emission area EA2, and a third emission area EA3.

Referring to FIG. 5, each of the pixels PX may include a first emission area EA1 that is the emission area of the first pixel PX1, a second emission area EA2 that is the emission area of the second pixel PX2, and a third emission area EA3 that is the emission area of the third pixel PX3.

Each of the first emission area EA1, the second emission area EA2 and the third emission area EA3 may have, but is not limited to, a polygonal, circular, oval or irregular shape in a plan view.

The maximum length of the third emission area EA3 in the first direction DR1 may be smaller than the maximum length of the second emission area EA2 in the first direction DR1 and the maximum length of the first emission area EA1 in the first direction DR1. The maximum length of the second emission area EA2 in the first direction DR1 may be substantially equal to the maximum length of the first emission area EA1 in the first direction DR1.

The maximum length of the third emission area EA3 in the second direction DR2 may be greater than the maximum length of the second emission area EA2 in the second direction DR2 and the maximum length of the first emission area EA1 in the second direction DR2. The maximum length of the third emission area EA3 in the second direction DR2 may be greater than the maximum length of the second emission area EA2 in the second direction DR2. The maximum length of the first emission area EA1 in the second direction DR2 may be smaller than the maximum length of the second emission area EA2 in the second direction DR2.

The first emission area EA1, the second emission area EA2 and the third emission area EA3 may have a hexagonal shape consisting of six straight lines as shown in FIG. 5 in a plan view. It should be understood, however, that the embodiments of the disclosure are not limited thereto. In another embodiment, the first emission area EA1, the second emission area EA2 and the third emission area EA3 may have a polygonal shape other than a hexagon, a circular shape, an elliptical shape or an irregular shape in a plan view.

As shown in FIG. 5, in each of the pixels PX, the first emission area EA1 and the second emission area EA2 may be adjacent to each other in the second direction DR2. The first emission area EA1 and the third emission area EA3 may be adjacent to each other in the first direction DR1. The second emission area EA2 and the third emission area EA3 may be adjacent to each other in the first direction DR1. The first emission area EA1, the second emission area EA2 and the third emission area EA3 may have different areas.

The first emission area EA1 may emit light of a first color, the second emission area EA2 may emit light of a second color, and the third emission area EA3 may emit light of a third color. The light of the first color may be light of a blue wavelength range, the second light may be light of a green wavelength range, and the third light may be light of a red wavelength range. For example, the blue wavelength range may refer that the main peak wavelength of light lies in the wavelength range of approximately 380 nm to approximately 480 nm, the green wavelength range may refer that the main peak wavelength of light lies in the wavelength range of approximately 480 nm to approximately 560 nm, and the red wavelength range may refer to that the main peak wavelength of light lies in the wavelength range of approximately 600 nm to approximately 750 nm.

Although each of the pixels PX includes three emission areas EA1, EA2 and EA3 in the embodiment shown in FIG. 5, the embodiments of the disclosure are not limited thereto. For example, each of the pixels PX may include four emission areas.

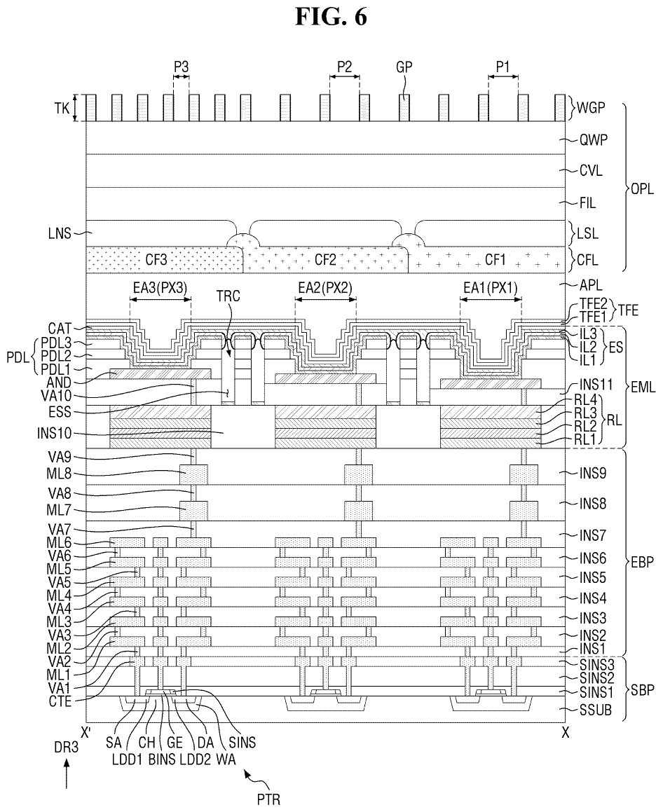

The layout of the emission areas of the pixels PX is not limited to that shown in FIG. 5. For example, the emission areas of the pixels PX may have a stripe structure in which the emission areas are arranged in the first direction DR1, a PenTile® matrix in which the emission areas have a diamond arrangement, or a hexagonal structure in which emission areas having a hexagonal shape in a plan view are arranged as shown in FIG. 6.

FIG. 6 is a schematic cross-sectional view of the display panel 100 taken along line X-X′ of FIG. 5 according to an embodiment.

Referring to FIG. 6, the display panel 100 may include a semiconductor backplane SBP, a light-emitting element backplane EBP, a display element layer EML, an encapsulation layer TFE, and an optical layer OPL.

The semiconductor backplane SBP may include a semiconductor substrate SSUB including multiple pixel transistors PTR, multiple semiconductor insulating films covering the pixel transistors PTR, and multiple contact terminals CTE that are electrically connected to the pixel transistors PTR, respectively. The pixel transistors PTR may be the first to sixth transistors T1 to T6 described above with reference to FIG. 4.

The semiconductor substrate SSUB may be a silicon substrate, a germanium substrate, or a silicon-germanium substrate. The semiconductor substrate SSUB may be a substrate doped with first-type impurities. Multiple well areas WA may be located in the upper surface of the semiconductor substrate SSUB. The well areas WA may be doped with second-type impurities. The second-type impurities may be different from the first-type impurities. For example, in case that the first-type impurities are p-type impurities, the second-type impurities may be n-type impurities. For example, in case that the first-type impurities are n-type impurities, the second-type impurities may be p-type impurities.

Each of the well areas WA may include a source region SA associated with a source electrode of a pixel transistor PTR, a drain region DA associated with a drain electrode of the pixel transistor PTR, and a channel region CH between the source region SA and the drain region DA.

A bottom insulating film BINS may be disposed between the gate electrode GE and the well areas WA. Side insulating films SINS may be disposed on the side surfaces of the gate electrode GE. The side insulating films SINS may be disposed on the bottom insulating film BINS.

Each of the source region SA and the drain region DA may be doped with the first-type impurities. The gate electrode GE of the pixel transistor PTR may overlap the well area WA in the third direction DR3. The channel region CH may overlap the gate electrode GE in the third direction DR3. The source area SA may be located on a side of the gate electrode GE, and the drain area SA may be located on an opposite side of the gate electrode GE.

Each of the well areas WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may have an impurity concentration lower than the source region SA due to the bottom insulating film BINS. The second low-concentration impurity region LDD2 may have an impurity concentration lower than the drain region SA due to the bottom insulating film BINS. The distance between the source region SA and the drain region DA may be increased by the first low-concentration impurity region LDD1 and the second low-concentration impurity region LDD2. Therefore, the length of the channel region CH of each of the pixel transistors PTR may be increased, and thus it is possible to prevent punch-through and hot carrier phenomenon due to short channel.

A first semiconductor insulating film SINS1 may be disposed on the semiconductor substrate SSUB. The first semiconductor insulating film SINS1 may be formed of, but is not limited to, a silicon carbon nitride (SiCN) or a silicon oxide (SiOx)-based inorganic film.

A second semiconductor insulating film SINS2 may be disposed on the first semiconductor insulating film SINS1. The second semiconductor insulating film SINS2 may be formed of a silicon oxide (SiOx)-based inorganic film, but the embodiments of the disclosure are not limited thereto.

Multiple contact terminals CTE may be disposed on the second semiconductor insulating film SINS2. Each of the contact terminals CTE may be connected to one of the gate electrode GE, the region SA and the drain region DA of each of the pixel transistors PTR through a hole penetrating the first semiconductor insulating film SINS1 and the second semiconductor insulating film INS2. The contact terminals CTE may be made of one of copper (Cu), aluminum (Al), tungsten (W), molybdenum (Mo), chromium (Cr), gold (Au), titanium (Ti), nickel (Ni) and neodymium (Nd), or an alloy containing one of these.

A third semiconductor insulating film SINS3 may be disposed on a side surface of each of the contact terminals CTE. The upper surface of each of the contact terminals CTE may not be covered by the third semiconductor insulating film SINS3 but may be exposed. The third semiconductor insulating film SINS3 may be formed of a silicon oxide (SiOx)-based inorganic film, but the embodiments of the disclosure are not limited thereto.

The semiconductor substrate SSUB may be replaced with a glass substrate or a polymer resin substrate including a material such as polyimide. Thin-film transistors may be disposed on a glass substrate or a polymer resin substrate. The glass substrate may be a rigid substrate that is not bendable, while the polymer resin substrate may be a flexible substrate that can be bent or curved.

The light-emitting element backplane EBP may include multiple conductive layers ML1 to ML8, multiple vias VA1 to VA9, and multiple insulating films INS1 to INS9. The light-emitting element backplane EBP may include multiple insulating films INS1 to INS11 disposed between the first to eighth conductive layers ML1 to ML8.

The first to eighth conductive layers ML1 to ML8 may serve to implement the circuit of the first pixel PX1 shown in FIG. 4 by connecting multiple contact terminals CTE exposed from the semiconductor backplane SBP. For example, the first to sixth transistors T1 to T6 may be formed in the semiconductor backplane SBP, and the connection of the first to sixth transistors T1 to T6 and the first capacitor C1 and the second capacitor C2 may be made through the first to eighth conductive layers ML1 to ML8. The connection between the drain region corresponding to the drain electrode of the fourth transistor T4, the source region corresponding to the source electrode of the fifth transistor T5, and the first electrode of the light-emitting element LE may be also made through the first to eighth conductive layers ML1 to ML8.

The first insulating film INS1 may be disposed on the semiconductor backplane SBP. Each of the first vias VA1 may penetrate the first insulating film INS1 and may be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate through the second insulating film INS2 to be connected to the exposed first conductive layer ML1. Each of the second conductive layers ML2 may be disposed on the second interlayer insulating film INS2 and may be connected to the second via VA2.

The third insulating film INS3 may be disposed over the second insulating film INS2 and the second conductive layers ML2. Each of the third vias VA3 may penetrate through the third insulating film INS3 to be connected to the exposed second conductive layer ML2. Each of the third conductive layers ML3 may be disposed on the third insulating film INS3 and may be connected to the third via VA3.

The fourth insulating film INS4 may be disposed over the third insulating film INS3 and the third conductive layers ML3. Each of the fourth vias VA2 may penetrate through the fourth insulating film INS4 to be connected to the exposed third conductive layer ML3. Each of the fourth conductive layers ML4 may be disposed on the fourth insulating film INS4 and may be connected to the fourth via VA4.

The fifth insulating film INS5 may be disposed over the fourth insulating film INS4 and the fourth conductive layers MLA. Each of the fifth vias VA5 may penetrate through the fifth insulating film INS5 to be connected to the exposed fourth conductive layer ML4. Each of the fifth conductive layers ML5 may be disposed on the fifth insulating film INS5 and may be connected to the fifth via VA5.

The sixth insulating film INS6 may be disposed over the fifth insulating film INS5 and the fifth conductive layers ML5. Each of the sixth vias VA6 may penetrate through the sixth insulating film INS6 to be connected to the exposed fifth conductive layer ML5. Each of the sixth conductive layers ML6 may be disposed on the sixth insulating film INS6 and may be connected to the sixth via VA6.

The seventh insulating film INS7 may be disposed over the sixth insulating film INS6 and the sixth conductive layers ML6. Each of the seventh vias VA7 may penetrate through the seventh insulating film INS7 to be connected to the exposed sixth conductive layer ML6. Each of the seventh conductive layers ML7 may be disposed on the seventh insulating film INS7 and may be connected to the seventh via VA7.

The eighth insulating film INS8 may be disposed over the seventh insulating film INS7 and the seventh conductive layers ML7. Each of the eighth vias VA8 may penetrate through the eighth insulating film INS8 to be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be made of substantially a same material. The first to eighth conductive layers ML1 to ML8 and the first to eighth vias VA1 to VA8 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. The first to eighth vias VA1 to VA8 may be made of substantially a same material. The first to eighth insulating films INS1 to ILD8 may be formed of a silicon oxide (SiOx)-based inorganic film, but embodiments of the specification are not limited thereto.

The thickness of the first conductive layer ML1, the thickness of the second conductive layer ML2, the thickness of the third conductive layer ML3, the thickness of the fourth conductive layer ML4, the thickness of the fifth conductive layer ML5 and the thickness of the sixth conductive layer ML6 may be greater than the thickness of the first via VA1, the thickness of the second via VA2, the thickness of the third via VA3, the thickness of the fourth via VA4, the thickness of the fifth via VA5 and the thickness of the sixth via VA6. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5 and the thickness of the sixth conductive layer ML6 may be substantially all equal. For example, the thickness of the first conductive layer ML1 may be approximately 1,360 Å, the thickness of the second conductive layer ML2, the thickness of the third conductive layer ML3, the thickness of the fourth conductive layer ML4, the thickness of the fifth conductive layer ML5 and the thickness of the sixth conductive layer ML6 may be approximately 1,440 Å, and the thickness of the first via VA1, the thickness of the second via VA2, the thickness of the third via VA3, the thickness of the fourth via VA4, the thickness of the fifth via VA5 and the thickness of the sixth via VA6 may be approximately 1,150 Å in the third direction DR3.

The thickness of the seventh conductive layer ML7 and the thickness of the eighth conductive layer ML8 may be greater than the thickness of the first conductive layer ML1, the thickness of the second conductive layer ML2, the thickness of the third conductive layer ML3, the thickness of the fourth conductive layer ML4, the thickness of the fifth conductive layer ML5 and the thickness of the sixth conductive layer ML6. The thickness of the seventh conductive layer ML7 and the thickness of the eighth conductive layer ML8 may be greater than the thickness of the seventh via VA7 and the thickness of the eighth via VA8. The thickness of the seventh via VA7 and the thickness of the eighth via VA8 may be greater than the thickness of the first via VA1, the thickness of the second via VA2, the thickness of the third via VA3, and the thickness of the fourth via VA4, the thickness of the fifth via VA5 and the thickness of the sixth via VA6. The thickness of the seventh conductive layer ML7 may be substantially equal to the thickness of the eighth conductive layer ML8. For example, the thickness of the seventh conductive layer ML7 and the thickness of the eighth conductive layer ML8 may be approximately 9,000 Å in the third direction DR3. The thickness of the seventh via VA7 and the thickness of the eighth via VA8 may be approximately 6,000 Å in the third direction DR3.

The ninth insulating film INS9 may be disposed over the eighth insulating film INS8 and the eighth conductive layer ML8. The ninth insulating film INS9 may be formed of an inorganic film of silicon oxide (SiOx) or the like, but the embodiments of the disclosure are not limited thereto.

Each of the ninth vias VA9 may penetrate through the ninth insulating film INS9 to be connected to the exposed eighth conductive layer ML8. The ninth vias VA9 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. The thickness of the ninth via VA9 may be approximately 16,500 Å in the third direction DR3.

The display element layer EML may be disposed on the light-emitting element backplane EBP. The display element layer EML may include a reflective electrode layer RL, tenth and eleventh insulating films INS10 and INS11, the tenth via VA10, light-emitting elements LE each including a first electrode AND, an emission stack ES and a second electrode CAT, and a pixel-defining layer PDL and multiple trenches TRC.

The reflective electrode layer RL may be disposed on the ninth insulating film INS9. The reflective electrode layer RL may include one or more reflective electrodes RL1, RL2, RL3 and RL4. For example, the reflective electrode layer RL may include a first to fourth reflective electrodes RL1, RL2, RL3 and RL4 as shown in FIG. 6.

The first reflective electrodes RL1 may be disposed on the ninth insulating film INS9 and may be connected to the ninth via VA9. The first reflective electrodes RL1 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. For example, the first reflective electrodes RL1 may include titanium nitride (TiN).

The second reflective electrodes RL2 may be disposed on the first reflective electrodes RL1. The second reflective electrodes RL2 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. For example, the second reflective electrodes RL2 may include aluminum (Al).

The third reflective electrodes RL3 may be disposed on the second reflective electrodes RL2. The third reflective electrodes RL3 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. For example, the third reflective electrodes RL3 may include titanium nitride (TiN).

The fourth reflective electrodes RL4 may be disposed on the third reflective electrodes RL3. The fourth reflective electrodes RL4 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. For example, the fourth reflective electrodes RL4 may include titanium (Ti).

Since the second reflective electrode RL2 is an electrode that substantially reflects light from the light-emitting elements LE, the thickness of the second reflective electrode RL2 may be greater than the thickness of the first reflective electrode RL1, the thickness of the third reflective electrode RL3 and the thickness of the fourth reflective electrode RL4. For example, the thickness of the first reflective electrode RL1, the thickness of the third reflective electrode RL3 and the thickness of the fourth reflective electrode RL4 may be approximately 100 Å, and the thickness of the second reflective electrode RL2 may be approximately 850 Å in the third direction DR3.

The tenth insulating film INS10 may be disposed on the ninth insulating film INS9. The tenth insulating film INS10 may be disposed between reflective electrode layers RL that are adjacent to one another in the horizontal direction. The tenth insulating film INS10 may be disposed on the reflective electrode layer RL in the third pixel PX3. The tenth insulating film INS10 may be formed of an inorganic film of silicon oxide (SiOx) or the like, but the embodiments of the disclosure are not limited thereto.

The eleventh insulating film INS11 may be disposed on the tenth insulating film INS10 and the reflective electrode layer RL. The eleventh insulating film INS11 may be formed of an inorganic film of silicon oxide (SiOx) or the like, but the embodiments of the disclosure are not limited thereto. The tenth insulating film INS10 and the eleventh insulating film INS11 may be optical auxiliary layers through which light that was emitted from the light-emitting elements LE and reflected by the reflective electrode layer RL passes.

In order to match the resonance distance of the light emitted from the light-emitting elements LE, the tenth insulating film INS10 and the eleventh insulating film INS11 may not be disposed under the first electrode AND of the first pixel PX1 in at least one of the first pixel PX1, the second pixel PX2 and the third pixel PX3. The first electrode AND of the first pixel PX1 may be disposed on (e.g., directly on) the reflective electrode layer RL. The eleventh insulating film INS11 may be disposed under the first electrode AND of the second pixel PX2. The tenth insulating film INS10 and the eleventh insulating film INS11 may be disposed under the first electrode AND of the third pixel PX3.

In summary, the distance between the first electrode AND and the reflective electrode layer RL in each of the first pixel PX1, the second pixel PX2 and the third pixel PX3 may be different. For example, in order to adjust the distance from the reflective electrode layer RL to the second electrode CAT according to the main wavelength of light emitted from each of the first pixel PX1, the second pixel PX2 and the third pixel PX3, it may be determined whether to dispose the tenth insulating film INS10 and the eleventh insulating film INS11 in each of the first pixel PX1, the second pixel PX2 and the third pixel PX3. In the embodiment shown in FIG. 6, the distance between the first electrode AND and the reflective electrode layer RL in the third pixel PX3 is greater than the distance between the first electrode AND and the reflective electrode layer RL in the second pixel PX2 and the distance between the first electrode AND and the reflective electrode layer RL in the first pixel PX1. In the embodiment, the distance between the first electrode AND and the reflective electrode layer RL in the second pixel PX2 is greater than the distance between the first electrode AND and the reflective electrode layer RL in the first pixel PX1. It should be understood, however, that the embodiments of the disclosure are not limited thereto.

Although the tenth insulating film INS10 and the eleventh insulating film INS11 are disposed according to the embodiment of the disclosure, a twelfth insulating film may be further disposed under the first electrode AND of the first pixel PX1. The eleventh insulating film INS11 and the twelfth insulating film may be disposed under the first electrode AND of the second pixel PX2, and the tenth insulating film INS10, the eleventh insulating film INS11 and the twelfth insulating film may be disposed under the first electrode AND of the third pixel PX3.

Each of the tenth vias VA10 may penetrate through the tenth insulating film INS10 and/or the eleventh insulating film INS11 to be connected to the exposed ninth conductive layer ML9 in the second pixel PX2 and the third pixel PX3. The tenth vias VA10 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. The thickness of the tenth via VA10 in the second pixel PX2 may be smaller than the thickness of the tenth via VA10 in the third pixel PX3.

The first electrode AND of each of the light-emitting elements LE may be disposed on the tenth insulating film INS10 and may be connected to the tenth via VA10. The first electrode AND of each of the light-emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth conductive layers ML1 to ML8 and the contact terminals CTE. The first electrode AND of each of the light-emitting elements LE may be made of one of copper (Cu), aluminum (Al), tungsten (W), molybdenum (Mo), chromium (Cr), gold (Au), titanium (Ti), nickel (Ni) and neodymium (Nd), or an alloy containing one of these. For example, the first electrode AND of each of the light-emitting elements LE may include titanium nitride (TiN).

The pixel-defining layer PDL may be disposed partially on the first electrode AND of each of the light-emitting elements LE. The pixel-defining layer PDL may cover the edge of the first electrode AND of each of the light-emitting elements LE. The pixel-defining layer PDL may serve to partition the first emission areas EA1, the second emission areas EA2 and the third emission areas EA3.

The first emission area EA1 may be defined as an area of the first pixel PX1 where the first electrode AND, the emission stack ES and the second electrode CAT are sequentially stacked on one another to emit light. The second emission area EA2 may be defined as an area of the second pixel PX2 where the first electrode AND, the emission stack ES and the second electrode CAT are sequentially stacked on one another to emit light. The third emission area EA3 may be defined as an area of the third pixel PX3 where the first electrode AND, the emission stack ES and the second electrode CAT are sequentially stacked on one another to emit light.

The pixel-defining layer PDL may include first to third pixel-defining layers PDL1, PDL2 and PDL3. The first pixel-defining layer PDL1 may be disposed on the edge of the first electrode AND of each of the light-emitting elements LE, the second pixel-defining layer PDL2 may be disposed on the first pixel-defining layer PDL1, and the third pixel-defining layer PDL3 may be disposed on the second pixel-defining layer PDL2. The first pixel-defining layer PDL1, the second pixel-defining layer PDL2 and the third pixel-defining layer PDL3 may be formed of a silicon oxide (SiOx)-based inorganic film, but the embodiments of the disclosure are not limited thereto. The thickness of the first pixel-defining layer PDL1, the second pixel-defining layer PDL2, and the third pixel-defining layer PDL3 may each be approximately 500 Å in the third direction DR3.

In case that the first pixel-defining layer PDL1, the second pixel-defining layer PDL2 and the third pixel-defining layer PDL3 are formed as a single pixel-defining layer, the height of the single pixel-defining layer may increase, and thus a first inorganic encapsulation film TFE1 may be broken due to step coverage. Herein, the step coverage refers to a ratio of a thin film applied on an inclined portion to the thin film applied on a flat portion. The lower the step coverage is, the more likely it is that the thin film would break at inclined portions.

Therefore, in order to prevent the first inorganic encapsulation film TFE1 from breaking due to step coverage, the first pixel-defining layer PDL1, the second pixel-defining layer PDL2 and the third pixel-defining layer PDL3 may have a cross-sectional structure in the form of stairs. For example, the width of the first pixel-defining layer PDL1 may be greater than the width of the second pixel-defining layer PDL2 and the width of the third pixel-defining layer PDL3, the width of the second pixel-defining layer PDL2 may be greater than the width of the third pixel-defining layer PDL3. The width of the first pixel-defining layer PDL1 refers to the horizontal length of the first pixel-defining layer PDL1 defined by the first direction DR1 and the second direction DR2.

Each of the trenches TRC may penetrate the first pixel-defining layer PDL1, the second pixel-defining layer PDL2, and the third pixel-defining layer PDL3. Each of the trenches TRC may penetrate the eleventh insulating film INS11. The tenth insulating film INS10 may be partially dug in each of the trenches TRC.

At least one trench TRC may be formed between adjacent pixels PX1, PX2 and PX3.

Although two trenches TRC are formed between adjacent pixels PX1, PX2 and PX3 in the embodiment shown in FIG. 6, the embodiments of the disclosure are not limited thereto.

The emission stack ES may include multiple intermediate layers. Although the emission stack ES has a three-tandem structure including a first stack layer IL1, a second stack layer IL2 and a third stack layer IL3 in the embodiment shown in FIG. 6, the embodiments of the disclosure are not limited thereto. For example, the emission stack ES may have a two-tandem structure including two intermediate layers.

In the three-tandem structure, the emission stack ES may have a tandem structure including multiple stack layers IL1, IL2 and IL3 emitting different lights. For example, the emission stack ES may include a first stack layer IL1 that emits light of a first color, a second stack layer IL2 that emits light of a second color, and a third stack layer IL3 that emits light of a third color. The first stack layer IL1, the second stack layer IL2 and the third stack layer IL3 may be sequentially stacked on one another.

The first stack layer IL1 may have a structure in which a first hole transport layer, a first organic emissive layer that emits light of the first color, and a first electron transport layer are sequentially stacked on one another. The second stack layer IL2 may have a structure in which a second hole transport layer, a second organic emissive layer that emits light of the second color, and a second electron transport layer are sequentially stacked on one another. The third stack layer IL3 may have a structure in which a third hole transport layer, a third organic emissive layer that emits light of the third color, and a third electron transport layer are sequentially stacked on one another. The emission stack may output white light in which light of the first color (e.g., red light) from the first organic emissive layer, light of the second color (e.g., green light) from the second organic emissive layer, and light of the third color (e.g., blue light) from the third organic emissive layer are mixed. Accordingly, white light may be provided from the first emission area EA1, the second emission area EA2, and the third emission area EA3. White light having passed through the first emission area EA1 may be incident on the first color filter CF1, white light having passed through the second emission area EA2 may be incident on the second color filter CF2, and white light having passed through the third emission area EA3 may be incident on the third color filter CF3.

A first charge generation layer may be disposed between the first stack layer IL1 and the second stack layer IL2 to supply charges to the second stack layer IL2 and electrons to the first stack layer IL1. The first charge generation layer may include an n-type charge generation layer that supplies electrons to the first stack layer IL1, and a p-type charge generation layer that supplies holes to the second stack layer IL2. The n-type charge generation layer may include a dopant of a metallic material.

A second charge generation layer may be disposed between the second stack layer IL2 and the third stack layer IL3 to supply charges to the third stack layer IL3 and electrons to the second stack layer IL2. The second charge generation layer may include an n-type charge generation layer that supplies electrons to the second stack layer IL2, and a p-type charge generation layer that supplies holes to the third stack layer IL3.

The first stack layer IL1 may be disposed on the first electrodes AND and the pixel-defining layer PDL, and may be disposed on the bottom of each of the trenches TRC. Due to the trenches TRC, the first stack layer IL1 may be disconnected between adjacent pixels PX1, PX2 and PX3. The second stack layer IL2 may be disposed on the first stack layer IL1. Due to the trenches TRC, the second stack layer IL2 may be disconnected between adjacent pixels PX1, PX2 and PX3. A void or an empty space ESS may be located between the first stack layer IL1 and the second stack layer IL2. The third stack layer IL3 may be disposed on the second stack layer IL2. The third stack layer IL3 may not be disconnected by the trenches TRC and may be disposed to cover the second stack layer IL2 in each of the trenches TRC. For example, in the three-tandem structure, each of the trenches TRC may be a feature that disconnects the first and second stack layers IL1 and IL2 of the display element layer EML, the first charge generation layer and the second charge generation layer between the adjacent pixels PX1, PX2 and PX3. In the two-tandem structure, each of the trenches TRC may be a feature that disconnects the charge generation layer and a lower intermediate layer disposed between the lower intermediate layer and an upper intermediate layer.

In order to stably disconnect the first and second stack layers IL1 and IL2 of the display element layer EML between the adjacent pixels PX1 PX2 and PX3, the height of each of the trenches TRC may be greater than the height of the pixel-defining layer PDL. The height of each of the trenches TRC refers to the length measured in the third direction DR3. The height of the pixel-defining layer PDL refer to the length of the pixel-defining layer PDL in the third direction DR3. In order to disconnect the first to third stack layers IL1, IL2 and IL3 of the display element layer EML, there may be other features than the trenches TRC between adjacent pixels PX1, PX2 and PX3. For example, instead of the trenches TRC, partition walls in the form of an inverse taper may be disposed on the pixel-defining layer PDL.

The number of the stack layers IL1, IL2 and IL3 emitting different lights is not limited to that shown in FIG. 6. For example, the emission stack ES may include two intermediate layers. One of the two intermediate layers may be substantially identical to the first stack layer IL1, and another one of the two intermediate layers may include a second hole transport layer, a second organic emissive layer, a third organic emissive layer, and a second electron transport layer. A charge generation layer may be disposed between the two intermediate layers to supply electrons to the one of the two intermediate layers and to supply charges to the another one of the two intermediate layers.

Although the first to third stack layers IL1, IL2 and IL3 are all disposed in the first emission area EA1, the second emission area EA2 and the third emission area EA3 in FIG. 6, the embodiments of the disclosure are not limited thereto. For example, the first stack layer IL1 may be disposed in the first emission area EA1 but not in the second emission area EA2 and the third emission area EA3. The second stack layer IL2 may be disposed in the second emission area EA2 but not in the first emission area EA1 and the third emission area EA3. The third stack layer IL3 may be disposed in the third emission area EA3 but not in the first emission area EA1 and the second emission area EA2. In this embodiment, the first to third color filters CF1, CF2 and CF3 of the optical layer OPL may be eliminated.

The second electrode CAT may be disposed on the third stack layer IL3. The second electrode CAT may be disposed on the third stack layer IL3 in each of multiple trenches TRC. The second electrode CAT may be formed of a transparent conductive material (TCP) such as ITO and IZO that can transmit light, or a semi-transmissive conductive material such as magnesium (Mg), silver (Ag) and an alloy of magnesium (Mg) and silver (Ag). In case that the second electrode CAT is formed of a semi-transmissive conductive material, the light extraction efficiency may be increased by using microcavities in each of the first to third pixels PX1, PX2 and PX3.

The encapsulation layer TFE may be disposed on the display element layer EML. The encapsulation layer TFE may include one or more inorganic films TFE1 and TFE2 to prevent permeation of oxygen or moisture into the display element layer EML. For example, the encapsulation layer TFEL may include a first inorganic encapsulation film TFE1 and a second inorganic encapsulation film TFE2.

The first inorganic encapsulation film TFE1 may be disposed on the second electrode CAT. The first inorganic encapsulation film TFE1 may be made up of multiple films in which one or more inorganic films of silicon nitride (SiNx), silicon oxynitride (SiON) and a silicon oxide (SiOx) are alternately stacked on one another. The first inorganic encapsulation film TFE1 may be formed by a chemical vapor deposition (CVD) process.

The second inorganic encapsulation film TFE2 may be disposed on the first inorganic encapsulation film TFE1. The second inorganic encapsulation film TFE2 may be formed of titanium oxide (TiOx) or aluminum oxide layer (AlOx), but the embodiments of the disclosure are not limited thereto. The second inorganic encapsulation film TFE2 may be formed by an atomic layer deposition (ALD) process. The thickness of the second inorganic encapsulation film TFE2 may be smaller than the thickness of the first inorganic encapsulation film TFE1.

An organic film APL may be a layer to increase the interfacial adhesion between the encapsulation layer TFE and the optical layer OPL. The organic film APL may include an acryl resin, an epoxy resin, a phenolic resin, a polyamide resin or a polyimide resin.

The optical layer OPL may include a color filter layer CFL, a lens layer LSL, a filling layer FIL, a cover layer CVL, a phase retardation layer QWP, and a wire grid polarizer WGP.

The color filter layer CFL may include multiple color filters CF1, CF2 and CF3. The color filters CF1, CF2 and CF3 may include first to third color filters CF1, CF2 and CF3. The first to third color filters CF1, CF2 and CF3 may be disposed on an adhesive layer ADL.

The first color filter CF1 may be in line with the first emission area EA1 (e.g., red emission area) of the first pixel PX1. The first color filter CF1 may transmit light of the first color, i.e., light in the red wavelength range. The red wavelength range may be in a range of approximately 600 nm to approximately 750 nm. Therefore, the first color filter CF1 may transmit light of the first color among the lights emitted from the first emission area EA1.

The second color filter CF2 may be in line with the second emission area EA2 (e.g., green emission area) of the second pixel PX2. The second color filter CF2 may transmit light of the second color, i.e., light in the green wavelength range. The green wavelength range may be in a range of approximately 480 nm to approximately 560 nm. Therefore, the second color filter CF2 may transmit light of the second color among the lights emitted from the second emission area EA2.

The third color filter CF3 may be in line with the third emission area EA3 (e.g., blue emission area) of the third pixel PX3. The third color filter CF3 may transmit light of the third color, i.e., light in the blue wavelength range. The blue wavelength range may be in a range of approximately 370 nm to approximately 460 nm. Therefore, the first color filter CF1 may transmit light of the first color among the lights emitted from the first emission area EA1.

The lens layer LSL may be disposed on the color filter layer CFL. The lens layer LSL may include multiple lenses LNS. The lenses LNS may be disposed on the first color filter CF1, the second color filter CF2 and the third color filter CF3, respectively. Each of the lenses LNS may be a structure for increasing the ratio of light directed to the front side of the display device 10. Each of the lenses LNS may have a cross-sectional shape that is convex upward.

The filling layer FIL may be disposed on the lens LSL. For example, the filling layer FIL may be disposed on multiple lenses LNS. The filling layer FIL may have a predetermined or selectable refractive index so that light travels in the third direction DR3 at the interface between the lenses LNS and the filling layer FIL. The filling layer FIL may be a planarization layer. The filling layer FIL may be an organic film including a material such as an acryl resin, an epoxy resin, a phenolic resin, a polyamide resin, and a polyimide resin.

The cover layer CVL may be disposed on the filling layer FIL. The cover layer CVL may be a glass substrate or a polymer resin such as a resin. The cover layer CVL may be a glass substrate or a polymer resin such as a resin. If the cover layer CVL is a glass substrate, the cover layer CVL may be attached to the filling layer FIL, and the filling layer FIL may adhere to the cover layer CVL. If the cover layer CVL is a glass substrate, the cover layer CVL may work as an encapsulation substrate. If the cover layer CVL is a polymer resin such as a resin, the cover layer CVL may be applied on (e.g., directly on) the filling layer FIL.

The phase retardation layer QWP (phase retardation plate or phase retardation film) may be disposed on the cover layer CVL. The phase retardation layer QWP may be a λ/4 plate (quarter-wave plate), but the embodiments of the disclosure are not limited thereto.

The wire grid polarizer WGP may be disposed on the phase retardation layer QWP. The wire grid polarizer WGP and the phase retardation layer QWP may form a polarizing member. For example, the polarizing member according to an embodiment may include the phase retardation layer QWP and the wire grid polarizer WGP.

The wire grid polarizer WGP may include multiple grid patterns GP. As shown in FIG. 5, each of the grid patterns GP may have a rectangular shape extended in the second direction DR2. As shown in FIG. 5, the grid patterns GP may be arranged in the first direction DR1. The grid patterns GP may be arranged such that they are spaced apart from one another in the first direction DR1. The wire grid polarizer WGP may include at least one of aluminum (Al), silver (Ag), and gold (Au). For example, each of the grid patterns GP may be made of a material containing at least one of aluminum (Al), silver (Ag), and gold (Au).

The wire grid polarizer WGP may transmit light in a particular polarization direction while reflecting lights in other polarization directions to recycle them. Such a wire grid polarizer WGP may be useful as a reflective polarizer because it can more effectively separate polarized lights than other polarizers can. For example, the wire grid polarizer WGP may be a device element that creates polarization using a conductive wire grid, and may have a structure in which multiple wires made of a conductive material on the phase retardation layer QWP are periodically arranged in parallel in nano size to form multiple grid patterns GP. In the wire grid polarizer WGP including multiple grid patterns GP, diffraction of an incident light may not occur if a gap between the grid patterns GP is smaller than the wavelength of the incident light. Therefore, the components of the incident light that have a vibration direction orthogonal to the conductive grid patterns GP, such as transverse magnetic (TM) polarization (e.g., P-wave), may be transmitted, whereas the components of the incident light that have a vibration direction parallel to the grid patterns GP, such as transverse electric (TE) polarization (e.g., S-wave), may be reflected. In other words, if the wire grid polarizer WGP has an arrangement period of the grid patterns GP shorter than the wavelength of the electromagnetic wave incident on the wire grid polarizer WGP, the polarization components (e.g., S-wave) parallel to the grid patterns GP may be reflected, whereas the polarization components (e.g., P-wave) perpendicular to the grid patterns GP may be transmitted. Since the wire grid polarizer WGP uses the grid patterns GP made of a metal, the efficiency of reflecting light is very high, so that the reflected light may be reflected again. By recycling lights, all lights may be converted into one polarized light.

According to an embodiment, the wire grid polarizer WGP may have a grid pattern GP with a smaller pitch in the third emission area EA3 through which blue light is transmitted (or the third emission area EA3 in line with the blue color filter CF3), and may have a grid pattern GP with a larger pitch in the first emission area EA1 or the second emission area EA2. In other words, the grid patterns GP of the wire grid polarizer WGP may have a smaller pitch in the third emission area EA3 than in the first emission area EA1 or in the second emission area EA2.

According to an embodiment, the grid patterns GP of the wire grid polarizer WGP that receive short-wavelength light, e.g., blue light, may have a smaller pitch (or spacing). For example, a third pitch P3 (or third spacing) may be smaller than a first pitch P1 (or first spacing) or a second pitch P2 (or second spacing), where the pitch of the grid patterns GP of the first pixel PX1 providing red light is defined as the first pitch P1 (or first spacing), the pitch of the grid patterns GP of the second pixel PX2 providing green light is defined as the second pitch P2 (or second spacing), and the pitch of the grid patterns GP of the third pixel PX3 providing blue light is defined as the third pitch P3. According to an embodiment of the disclosure, the first pitch P1 (or first spacing) may be equal to the second pitch P2 (or second spacing).

In other words, the third pitch P3 (or third spacing) may be smaller than the first pitch P1 (or first spacing) or the second pitch P2 (or second spacing), where the pitch of the grid patterns GP disposed on the first color filter CF1 transmitting red light is defined as the first pitch P1 (or first spacing), the pitch of the grid patterns GP disposed on the second color filter CF1 transmitting green light is defined as the second pitch P2 (or second spacing), and the pitch of the grid patterns GP disposed on the third color filter CF3 transmitting blue light is defined as the third pitch P3. According to an embodiment of the disclosure, the first pitch P1 (or first spacing) may be equal to the second pitch P2 (or second spacing). Accordingly, the transmittance of short-wavelength light, e.g., blue light, may be improved. In other words, as the transmittance of short-wavelength light is improved, the transmittance of blue light and the transmittance of other colors, such as green light and red light may be maintained at substantially a same level. Accordingly, the luminance balance between blue light, green light and red light can be improved.

According to an embodiment, a first pitch P1 may be in a range of about 100 nm to about 150 nm, a second pitch P2 may be in a range of about 100 nm to about 150 nm, and a third pitch P3 may be in a range of about 50 nm to about 90 nm.

According to an embodiment, at least one of the grid patterns GP of the wire grid polarizer WGP may have a thickness TK in a range of about 100 nm to about 300 nm. According to another embodiment, at least one of the grid patterns GP of the wire grid polarizer WGP may have a thickness TK in a range of about 100 nm to about 200 nm. According to an embodiment, all grid patterns GP of the wire grid polarizer WGP may have a same thickness TK.

FIG. 7 is a schematic cross-sectional view of the display panel 100 taken along line X-X′ of FIG. 5 according to an embodiment.

The display panel 100 of FIG. 7 is different from the display panel 100 of FIG. 6 in that a lens layer LSL is disposed at a different position. The following description will focus on the difference.

As shown in FIG. 7, the lens layer LSL may be disposed on the wire grid polarizer WGP. In other words, the wire grid polarizer WGP may be disposed between the phase retardation layer QWP and the lens layer LSL.

As in the embodiment shown in FIG. 7, the filling layer FIL may be disposed on (e.g., directly on) the color filter layer CFL. The filling layer FIL may be in contact with the color filter layer CFL.

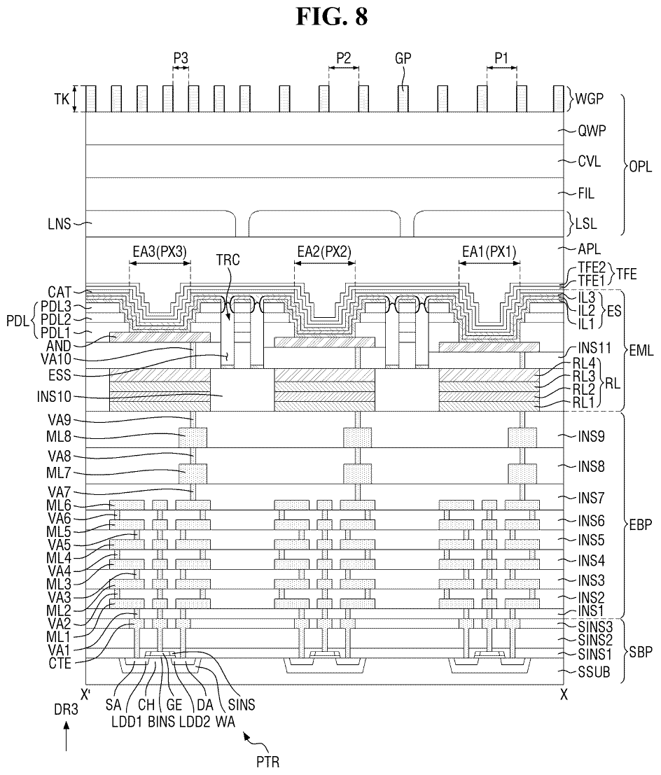

FIG. 8 is a schematic cross-sectional view of the display panel 100 taken along line X-X′ of FIG. 5 according to an embodiment.

The display panel 100 of FIG. 8 is different from the display panel 100 of FIG. 6 in that the former does not include the color filter CFL. The following description will focus on the difference. For example, the display panel 100 of FIG. 6 described above is a “white-OLED” display panel in which the emission stack ES of the pixels PX1, PX2 and PX3 included in the unit pixel UPX all provide white light, while a display panel 100 of FIG. 8, which will be described below, is an “RGB-OLED” display panel in which the emission stacks ES of the pixels PX1, PX2 and PX3 included in the unit pixel UPX provide red light, green light and blue light, respectively.

As shown in FIG. 8, since the display panel 100 does not include the color filter layer CFL, the organic film APL and the lens layer LSL may be in contact with each other.

According to an embodiment, the emission stack ES of FIG. 8 may provide lights of different colors for different pixels. For example, the emission stack ES of the first pixel PX1 may include a red organic emissive layer that provides red light, the emission stack ES of the second pixel PX2 may include a green organic emissive layer that provides green light, and the emission stack ES of the third pixel PX3 may include a blue organic emissive layer that provides blue light. In other words, the emission stack ES may include the red organic emissive layer in the first emission area EA1 of the first pixel PX1, the green organic emissive layer in the second emission area EA2 of the second pixel PX2, and the blue organic emissive layer in the third emission area EA3 of the third pixel PX3. Accordingly, the first pixel PX1 may provide red light generated by the red organic emissive layer, the second pixel PX2 may provide green light generated by the green organic emissive layer, and the third pixel PX3 may provide blue light generated by the blue organic emissive layer.

According to an embodiment, a third pitch P3 (or third spacing) may be smaller than a first pitch P1 (or first spacing) or a second pitch P2 (or second spacing), where the pitch of the grid patterns GP of the first pixel PX1 providing red light is defined as the first pitch P1 (or first spacing), the pitch of the grid patterns GP of the second pixel PX2 providing green light is defined as the second pitch P2 (or second spacing), and the pitch of the grid patterns GP of the third pixel PX3 providing blue light is defined as the third pitch P3. According to an embodiment of the disclosure, the first pitch P1 (or first spacing) may be equal to the second pitch P2 (or second spacing).

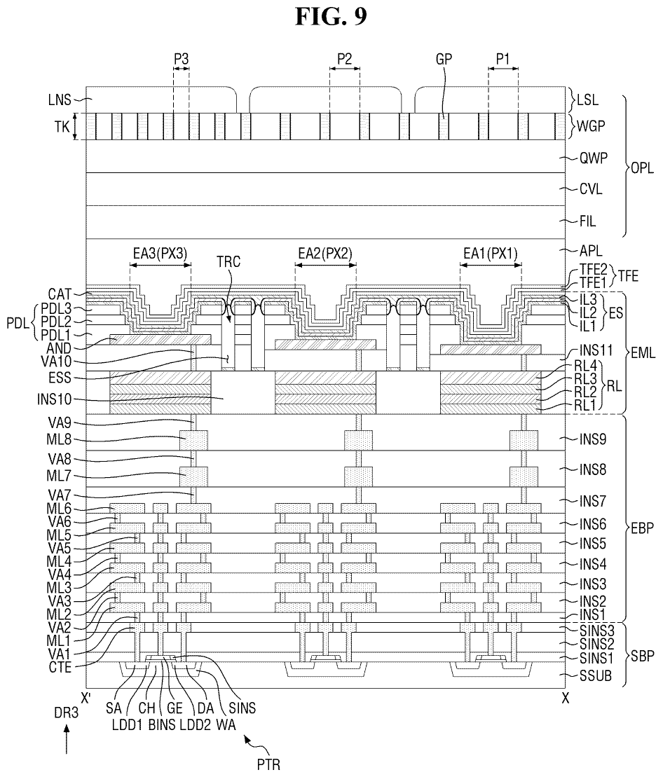

FIG. 9 is a schematic cross-sectional view of the display panel 100 taken along line X-X′ of FIG. 5 according to an embodiment.

The display panel 100 of FIG. 9 is different from the display panel 100 of FIG. 7 in that the former does not include the color filter CFL. The following description will focus on the difference.

As shown in FIG. 9, since the display panel 100 does not include the color filter layer CFL, the organic film APL and the lens layer LSL may be in contact with each other.

According to an embodiment, the emission stack ES of FIG. 9 may provide lights of different colors for different pixels. For example, the emission stack ES of the first pixel PX1 may include a red organic emissive layer that provides red light, the emission stack ES of the second pixel PX2 may include a green organic emissive layer that provides green light, and the emission stack ES of the third pixel PX3 may include a blue organic emissive layer that provides blue light. In other words, the emission stack ES may include the red organic emissive layer in the first emission area EA1 of the first pixel PX1, the green organic emissive layer in the second emission area EA2 of the second pixel PX2, and the red organic emissive layer in the third emission area EA3 of the third pixel PX3. Accordingly, the first pixel PX1 may provide red light generated by the red organic emissive layer, the second pixel PX2 may provide green light generated by the green organic emissive layer, and the third pixel PX3 may provide blue light generated by the blue organic emissive layer.

According to an embodiment, a third pitch P3 (or third spacing) may be smaller than a first pitch P1 (or first spacing) or a second pitch P2 (or second spacing), where the pitch of the grid patterns GP of the first pixel PX1 providing red light is defined as the first pitch P1 (or first spacing), the pitch of the grid patterns GP of the second pixel PX2 providing green light is defined as the second pitch P2 (or second spacing), and the pitch of the grid patterns GP of the third pixel PX3 providing blue light is defined as the third pitch P3. According to an embodiment of the disclosure, the first pitch P1 (or first spacing) may be equal to the second pitch P2 (or second spacing).

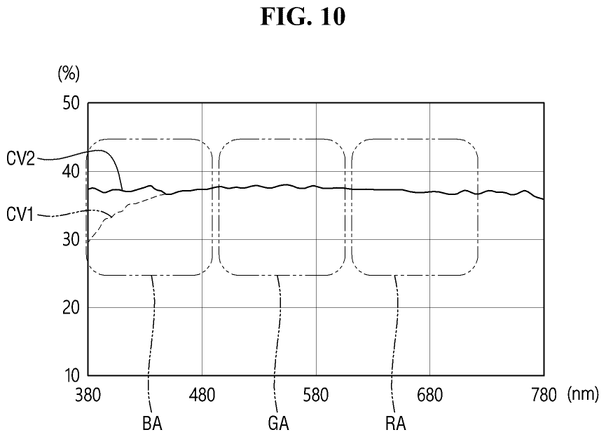

FIG. 10 is a graph for illustrating the effects of a display device according to an embodiment. For example, FIG. 10 is a graph showing the transmittance versus wavelength of light, where the x-axis denotes the wavelength of light in nm, and the y-axis denotes the light transmittance in %.

A first curve CV1 in the blue light wavelength region BA in FIG. 10 represents the transmittance of blue light of Comparative Example, while a second curve CV2 in the blue light wavelength region BA of FIG. 10 represents the transmittance of blue light of the display device according to an embodiment of the disclosure.

It can be seen from FIG. 10 that the transmittance of blue light in the blue light wavelength region BA can be improved according to the embodiment of the disclosure. Accordingly, according to the embodiment, the luminance of light in the blue light wavelength region BA, the luminance of light in the green light wavelength region GA and the luminance of light in the red light wavelength region RA may be maintained at substantially a same level. Accordingly, the luminance balance between blue light, green light and red light may be improved.

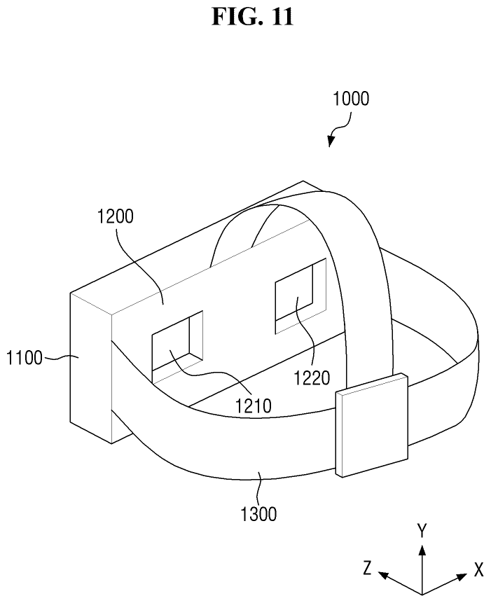

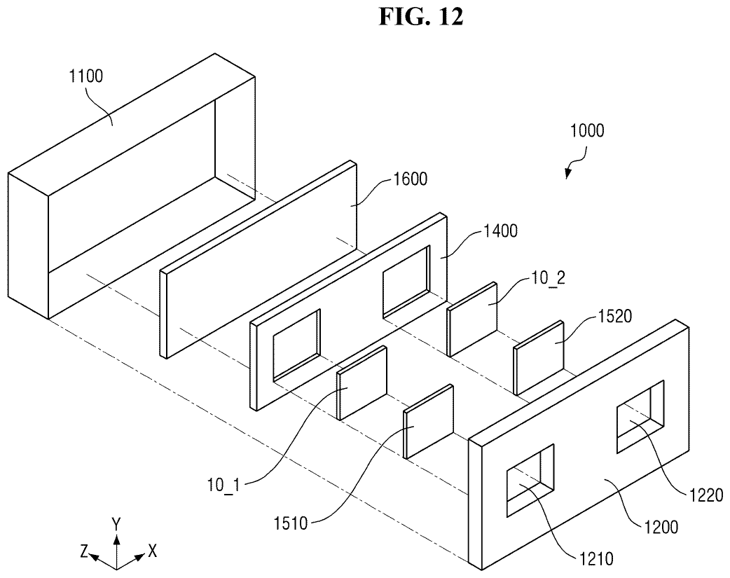

FIG. 11 is a perspective view showing a head-mounted display according to an embodiment of the disclosure. FIG. 12 is an exploded perspective view of the head-mounted display of FIG. 11 according to an embodiment.

Referring to FIGS. 11 and 12, a head-mounted display device 1000 according to an embodiment may include a first display device 10_1, a second display device 10_2, a display device housing 1100, a housing cover 1200, a first eyepiece 1210, a second eyepiece 1220, a head strap band 1300, a middle frame 1400, a first optical member 1510, a second optical member 1520, and a control circuit board 1600.

The first display device 10_1 may provide images to a user's left eye, and the second display device 10_2 may provide images to the user's right eye. The first display device 10_1 and the second display device 10_2 are substantially identical to the display device 10 described above with reference to FIGS. 1 and 2; and, therefore, the redundant description will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600, and may be disposed between the second display device 10_2 and the control circuit board 1600. The middle frame 1400 may support and fix the first display device 10_1, the second display device 10_2 and the control circuit board 1600.

The control circuit board 1600 may be disposed between the middle frame 1400 and the display device housing 1100. The control circuit board 1600 may be connected to the first display device 10_1 and the second display device 10_2 through a connector. The control circuit board 1600 may convert an image source input from the outside into digital video data (DATA) and may transmit the digital video data (DATA) to the first display device 10_1 and the second display device 10_2 through the connector.

The control circuit board 1600 may transmit digital video data (DATA) associated with a left eye image optimized for the user's left eye to the first display device 10_1, and may transmit digital video data (DATA) associated with a right eye image optimized for the user's right eye to the second display device 10_2. In another embodiment, the control circuit board 1600 may transmit a same digital video data (DATA) to the first display device 10_1 and the second display device 10_2.

The display device housing 1100 may accommodate the first display device 10_1, the second display device 10_2, the middle frame 1400, the first optical member 1510, the second optical member 1520, and the control circuit board 1600. The housing cover 1200 may cover the open face of the housing 1100. The housing cover 1200 may include the first eyepiece 1210 where the user's left eye is placed, and the second eyepiece 1220 where the user's right eye is placed. Although the first eyepiece 1210 and the second eyepiece 1220 are separately disposed in the embodiment shown in FIGS. 11 and 12, the embodiments of the disclosure are not limited thereto. The first eyepiece 1210 and the second eyepiece 1220 may be combined into a single element.

The first eyepiece 1210 may be aligned with the first display device 10_1 and the first optical member 1510, and the second eyepiece 1220 may be aligned with the second display device 10_2 and the second optical member 1520. Therefore, a user may see virtual images of images on the first display device 10_1 magnified by the first optical member 1510 through the first eyepiece 1210, and virtual images of images on the second display device 10_2 magnified by the second optical member 1520 through the second eyepiece 1220.

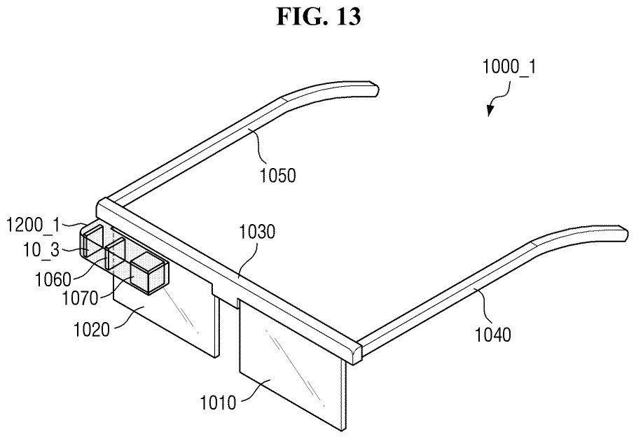

The head strap band 1300 may fix the housing 1100 to the user's head so that the first eyepiece 1210 and the second eyepiece 1220 of the housing cover 1200 remain in line with the user's left and right eyes, respectively. By implementing a light and small display device housing 1200, the head-mounted display device 1000 may include an eyeglasses frame as shown in FIG. 13 instead of a head strap band 800.

The head-mounted display device 1000 may further include a battery for supplying power, an external memory slot for inserting an external memory, and an external connection port and a wireless communication module for receiving an image source. The external connection port may be a USB (universe serial bus) terminal, a display port, or an HDMI (high-definition multimedia interface) terminal. The wireless communication module may be a 5G communication module, a 4G communication module, a Wi-Fi module, or a Bluetooth module.

FIG. 13 is a perspective view of a head-mounted display device according to an embodiment of the disclosure.

Referring to FIG. 13, the head-mounted display device 1000_1 according to an embodiment may be a glasses-type display device with a light and small display device housing 1200_1. The head-mounted display device 1000_1 according to an embodiment may include display devices 10_3, a left-eye lens 1010, a right-eye lens 1020, a support frame 1030, eyeglass temples 1040 and 1050, optical members 1600, optical path conversion members 1070, and display device housings 1200_1.

The display device housings 1200_1 may include the display devices 10_3, the optical members 1600, and the optical path conversion members 1070. The images displayed on the display device 10_3 may be enlarged by the optical members 1060, and the optical paths of the images may be converted by the optical path conversion member 1070 to be provided to the user's right eye through the right eye lens 1020. As a result, the user can see, with the right eye, augmented reality images that combine virtual images displayed on the display device 10_3 and real world images viewed through the right eye lens 1020.

Although the display device housing 1200_1 is disposed at the right end of the support frame 1030 in the embodiment shown in FIG. 13, the embodiments of the disclosure are not limited thereto. For example, the display device housing 1200_1 may be disposed at the left end of the support frame 1030, and images displayed on the display device 10_3 may be provided to the user's left eye. In another embodiment, the display device housing 1200_1 may be disposed at both the left and right ends of the support frame 1030, and the user can watch images displayed on the display device 10_3 through both the left and right eyes.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first electrode on a substrate;
an emissive layer on the first electrode;
a second electrode on the emissive layer; and
a wire grid polarizer on the second electrode, wherein
the wire grid polarizer comprises a plurality of grid patterns, and
a pitch between the plurality of grid patterns arranged in a blue emission area of a blue pixel providing blue light is smaller than pitches between the plurality of grid patterns arranged in emission areas of pixels providing different lights from the blue light in a horizontal direction.

2. The display device of claim 1, wherein the pixels providing the different lights comprises:
a green pixel providing green light; and
a red pixel providing red light.

3. The display device of claim 2, wherein the pitch between the plurality of grid patterns arranged in a green emission area of the green pixel and the pitch between the plurality of grid patterns arranged in a red emission area of the red pixel are equal.

4. The display device of claim 1, further comprising:
a phase retardation layer between the second electrode and the wire grid polarizer.

5. The display device of claim 1, further comprising:
a color filter layer between the second electrode and the wire grid polarizer.

6. The display device of claim 5, wherein the color filter layer comprises:
a red color filter that transmits red light;
a green color filter that transmits green light; and
a blue color filter that transmits the blue light

7. The display device of claim 6, wherein a pitch between the plurality of grid patterns arranged in line with the blue color filter is smaller than a pitch between the plurality of grid patterns arranged in line with the green color filter.

8. The display device of claim 6, wherein a pitch between the plurality of grid patterns arranged in line with the blue color filter is smaller than a pitch between the plurality of grid patterns arranged in line with the red color filter.

9. The display device of claim 1, wherein the pitch between the plurality of grid patterns arranged in the blue emission area is in a range of about 50 nm to about 90 nm.

10. The display device of claim 1, wherein the pitches between the plurality of grid patterns arranged in the emission areas of the pixels providing the different lights are in a range of about 100 nm to about 150 nm.

11. The display device of claim 1, wherein at least one of the plurality of grid patterns of the wire grid polarizer has a thickness in a range of about 100 nm to about 300 nm.

12. The display device of claim 1, wherein the wire grid polarizer includes at least one of aluminum, silver, and gold.

13. The display device of claim 1, further comprising:
a lens layer between the second electrode and the wire grid polarizer.

14. The display device according to claim 1, further comprising:
a lens layer on the wire grid polarizer.

15. An optical device comprising:
a display device; and
an optical path conversion member above the display device, wherein
the display device comprises:
a first electrode on a substrate;
an emissive layer on the first electrode;
a second electrode on the emissive layer; and
a wire grid polarizer on the second electrode,
the wire grid polarizer comprises a plurality of grid patterns, and
a pitch between the plurality of grid patterns arranged in a blue emission area of a blue pixel providing blue light is smaller than pitches between the plurality of grid patterns arranged in emission areas of pixels providing different lights from the blue light in a horizontal direction.

16. The optical device of claim 15, wherein the pixels providing the different lights comprise:
a green pixel providing green light; and
a red pixel providing red light.

17. The optical device of claim 16, wherein the pitch between the plurality of grid patterns arranged in a green emission area of the green pixel and the pitch between the plurality of grid patterns arranged in a red emission area of the red pixel are equal.

18. The optical device of claim 15, further comprising:
a phase retardation layer between the second electrode and the wire grid polarizer.

19. The optical device of claim 15, further comprising:
a color filter layer between the second electrode and the wire grid polarizer.

20. The optical device of claim 19, wherein the color filter layer comprises:
a red color filter that transmits red light;
a green color filter that transmits green light; and
a blue color filter that transmits the blue light.

21. The optical device of claim 20, wherein a pitch between the plurality of grid patterns arranged in line with the blue color filter is smaller than a pitch between the plurality of grid patterns arranged in line with the green color filter.

22. The optical device of claim 20, wherein a pitch between the plurality of grid patterns arranged in line with the blue color filter is smaller than a pitch between the plurality of grid patterns arranged in line with the red color filter.
